(19) United States
(12) Patent Application Publication
(10) Pub. No.: US 2010/0304311 A1
(43) Pub. Date: Dec. 2, 2010

(54) METHOD OF PRODUCING RESIST PATTERN

(76) Inventors: Katsuo OSHIMA, Miyagi (JP); Tokio Shino, Saitama (JP)

Correspondence Address: Kubotera & Associates, LLC, 200 Daingerfield Rd, Suite 202, Alexandria, VA, 22314, US

(21) Appl. No.: 12/786,932

(22) Filed: May 25, 2010

(30) Foreign Application Priority Data
May 28, 2009 (JP) 2009-128924

(51) Int. Cl. G03F 7/20

(52) U.S. Cl. 430/325

(57) ABSTRACT

A method of producing a resist pattern includes the steps of: forming a resist layer on the semiconductor substrate; performing a first exposure process on the resist layer; performing a first developing process for developing the resist layer to form a first resist pattern having an excess region; performing a first cleaning process; performing a second exposure process on the first resist pattern; performing a second developing process on the first resist pattern to remove the excess region from the first resist pattern so that a second resist pattern corresponding to the specific resist pattern is formed; and performing a second cleaning process.

### BACKGROUND OF THE INVENTION AND RELATED ART STATEMENT

The present invention relates to a method of producing a resist pattern. More specifically, the present invention relates to a method of producing a resist pattern through a photolithography process of a semiconductor manufacturing process.

In a conventional manufacturing process of a semiconductor device such as an LSI (Large Scale Integrated circuit), a resist pattern is generally produced through a photolithography process. In the photolithography process, first, a photo resist is coated on an entire surface of a semiconductor substrate (a semiconductor wafer). In the next step, the photo resist is exposed using a reticle or a mask having a designed semiconductor integrated circuit pattern. Afterward, a desired resist pattern corresponding to the designed semiconductor integrated circuit pattern is produced through a baking process, a developing process, and a cleaning process.

The developing process generally includes a so-called paddle developing process (refer to Patent Reference). In the paddle developing process, first, a resist film is formed on a surface of an object to be processed such as a semiconductor wafer and the like, and the resist film is exposed. In the next step, a developing liquid is applied on the resist film from a developing liquid nozzle. At this moment, the semiconductor wafer is attached to a spin chuck, so that the semiconductor wafer is rotating. Accordingly, when the developing liquid is applied on the resist film, the developing liquid spreads toward a circumference portion of the semiconductor wafer. In the next step, the semiconductor wafer stops, so that the developing liquid stays on the resist film through surface tension.

Patent Reference: Japanese Patent Publication No. 11-238676

In the next step, the semiconductor wafer is rotated with the spin chuck one more time. As a result, the developing liquid starts moving toward the circumference portion of the semiconductor wafer through a centrifugal force. Afterward, the spin chuck stops to stop the semiconductor wafer, and the stationary state is maintained for a specific period of time. When the semiconductor wafer stops, the developing liquid situated at the circumference portion of the semiconductor wafer returns to a central portion of the semiconductor wafer. In other words, the developing liquid returns to a distribution of an equilibrium state.

In the next step, while the semiconductor wafer is rotating with the spin chuck, purified water is applied through a purified water nozzle, so that the purified water washes away the developing liquid, thereby cleaning the semiconductor wafer with the purified water. Lastly, the semiconductor wafer rotates to spin off the purified water, so that the resist formed on a surface of the semiconductor wafer is dried. Afterward, the cleaning process with the purified water and the drying process through the rotation of the semiconductor wafer are repeated.

A compatibility effect of a resist will be explained next. FIG. 2 is a graph showing a relationship between a solubility speed of a resist component and a red cloud density. The red cloud represents a developing liquid in which the resist component is dissolved. In the compatibility effect, the resist component is dissolved into the developing liquid, so that the solubility speed of the resist component increases.

In FIG. 2, a neutralization reaction represents a phenomenon in which a developing liquid component (TMAH) is neutralized with the resist component, so that a developing speed decreases.

In the developing process of the conventional manufacturing process described above, it is difficult to maintain a dimensional uniformity of a resist pattern depending on a pattern ratio. More specifically, an amount of a resist component dissolved into the developing liquid depends on the pattern ratio. When the pattern ratio is small, a large amount of the resist component is dissolved into the developing liquid. Accordingly, a density distribution of the red cloud becomes uneven with respect to the surface of the semiconductor wafer.

As shown in FIG. 2, when the density of the red cloud changes, the solubility speed of the resist component changes accordingly. As a result, the density distribution of the red cloud becomes uneven with respect to the surface of the semiconductor wafer.

In view of the problems described above, an object of the present invention is to provide a method of producing a resist pattern capable of solving the problems of the conventional method of producing the resist pattern. In the present invention, it is possible to produce the resist pattern with good dimension uniformity regardless of a pattern ratio.

Further objects and advantages of the invention will be apparent from the following description of the invention.

### SUMMARY OF THE INVENTION

In order to attain the objects described above, according to an aspect of the present invention, a method of producing a resist pattern on a semiconductor substrate includes the steps of: forming a resist layer on the semiconductor substrate; performing a first exposure process on the semiconductor substrate with the resist layer formed thereon so that an excess region is formed around a desired resist pattern; performing a first developing process after the first exposure is performed; performing a first cleaning process to form a first resist pattern having the excess region after the first developing process is performed; performing a second exposure process on the semiconductor substrate with the first resist pattern formed thereon corresponding to the desired resist pattern; performing a second developing process after the second exposure is performed; and performing a second cleaning process to form the desired resist pattern without the excess region after the second developing process is performed.

In the aspect of the present invention, the first developing process and the second developing process are performed to form the desired resist pattern. Accordingly, in the second developing process, only a small amount of a resist is developed (dissolved). As a result, it is possible to produce the desired resist pattern with good dimensional uniformity regardless of a pattern ratio.

### BRIEF DESCRIPTION OF THE DRAWINGS

FIGS. 1(A) to 1(E) are schematic sectional views showing a method of producing a resist pattern according to an embodiment of the present invention;

FIG. 2 is a graph showing a relationship between a solubility speed of a resist component and a red cloud density;

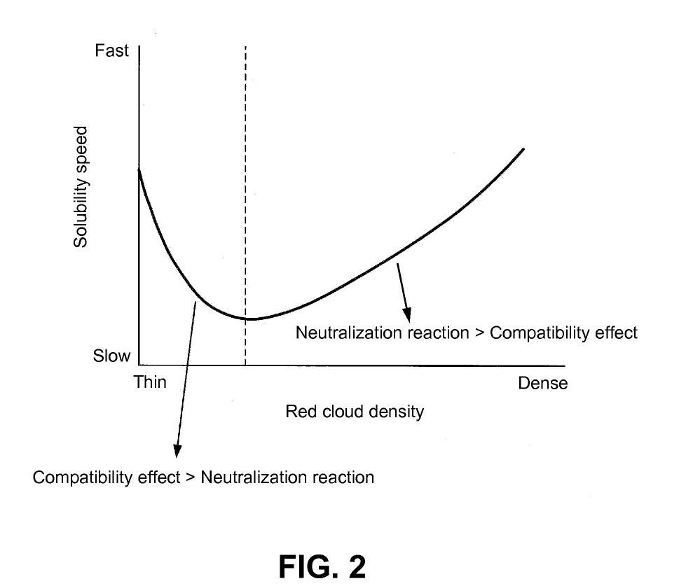

FIG. 3 is a graph showing a relationship between a ratio (an area) of the resist pattern and a dimensional variance (a standard deviation of 213 points over a surface of a wafer ×3) of the resist pattern according to the embodiment of the present invention; and

FIG. 4 is a graph showing a relationship between the ratio (the area) of the resist pattern and a dimensional variance (a difference between a maximum dimension and a minimum dimension) of the resist pattern according to the embodiment of the present invention.

### DETAILED DESCRIPTION OF PREFERRED EMBODIMENTS

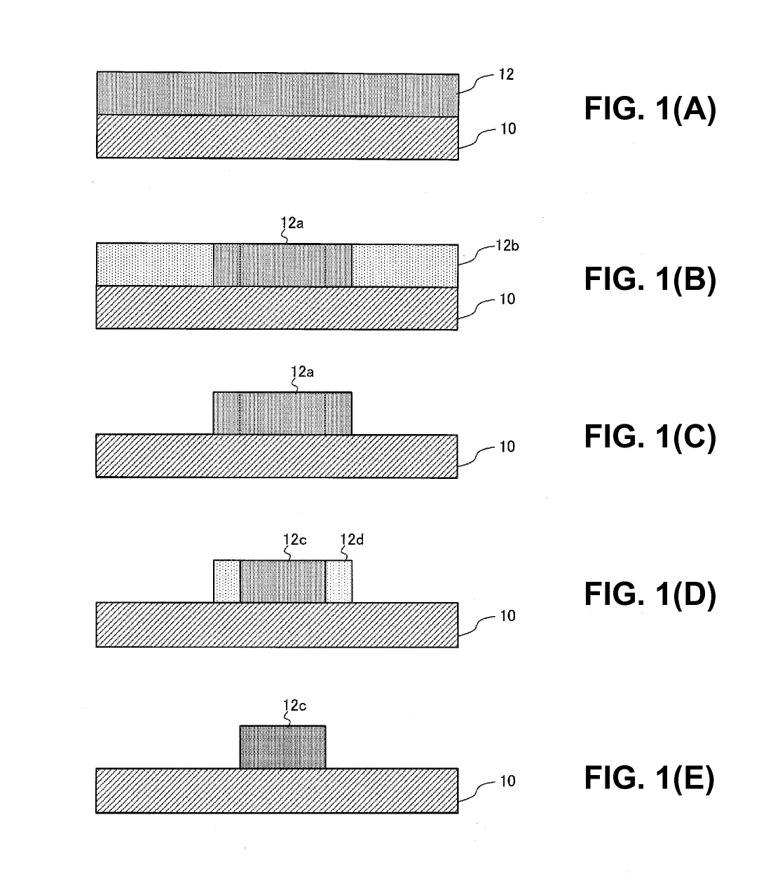

Hereunder, preferred embodiments of the present invention will be explained with reference to the accompanying drawings. FIGS. 1(A) to 1(E) are schematic sectional views showing a method of producing a resist pattern according to an embodiment of the present invention.

As shown in FIG. 1(A), first, a resist film 12 of a positive type is formed on a surface of a semiconductor wafer 10. In the next step, a first exposure process is performed using a first reticle or a first mask in which a specific semiconductor integrated circuit pattern is drawn. At this moment, the first exposure process is performed such that an excess region 12d is formed around a circumference of a desired semiconductor integrated circuit pattern.

More specifically, the first reticle or the first mask includes a first resist pattern 12a corresponding to the specific semiconductor integrated circuit pattern and including the excess region 12d, so that the excess region 12d extends into a wiring portion by a specific distance (for example, a few nanometers).

As shown in FIG. 1(B), the first resist pattern 12a includes the excess region 12d, and a region 12b is to be developed (dissolved) in a first developing process (described below).

In the next step, a developing liquid is applied on the resist film 12 from a developing liquid nozzle. At this moment, the semiconductor wafer 10 is attached to a spin chuck, so that the semiconductor wafer 10 is rotating. Accordingly, when the developing liquid is applied on the resist film 12, the developing liquid spreads toward a circumference portion of the semiconductor wafer 10. In the next step, the semiconductor wafer 10 stops, so that the developing liquid stays on the resist film through surface tension.

In the next step, the semiconductor wafer 10 is rotated with the spin chuck one more time. As a result, the developing liquid starts moving toward the circumference portion of the semiconductor wafer 10 through a centrifugal force. Afterward, the spin chuck stops to stop the semiconductor wafer 10, and the stationary state is maintained for a specific period of time. When the semiconductor wafer 10 stops rotating, the developing liquid situated at the circumference portion of the semiconductor wafer 10 returns to a central portion of the semiconductor wafer 10. In other words, the developing liquid returns to a distribution of an equilibrium state. In the first developing process described above, the developing liquid is still distributed unevenly to a relatively large extent.

In the next step as a first cleaning process, while the semiconductor wafer 10 is rotating with the spin chuck, purified water is applied through a purified water nozzle, so that the purified water washes away the developing liquid, thereby cleaning the semiconductor wafer 10 with the purified water. Lastly, the semiconductor wafer 10 rotates to spin off the purified water, so that the first resist pattern 12a formed on the surface of the semiconductor wafer is dried. Afterward, the cleaning process with the purified water and the drying process through the rotation of the semiconductor wafer 10 are repeated.

As shown in FIG. 1(C), after the steps described above are performed, the first resist pattern 12a with the excess region 12d is formed on the semiconductor wafer 10. Note that a large portion of a resist component dissolved in the developing liquid is removed in the first developing process and the first cleaning process.

In the next step, as shown in FIG. 1(D), a second exposure process is performed using a second reticle or a second mask in which the desired semiconductor integrated circuit pattern is drawn. Different from the first reticle or the first mask, the second reticle or the second mask includes the wiring portion with an exact width, and does not include the excess region 12d. In FIG. 1(D), a second resist pattern 12c corresponds to the desired semiconductor integrated circuit pattern, and the excess region 12d is developed (dissolved) in a second developing process (described below).

In the next step, similar to the first developing process, the second developing process is performed. In the second developing process, as compared with the first developing process, a small amount of the resist component is dissolved in the developing liquid. Accordingly, a concentration of the developing liquid has a small distribution.

In the next step, similar to the first cleaning process, a second cleaning process is performed. As a result, as shown in FIG. 1(E), the second resist pattern 12c is formed as the desired semiconductor integrated circuit pattern.

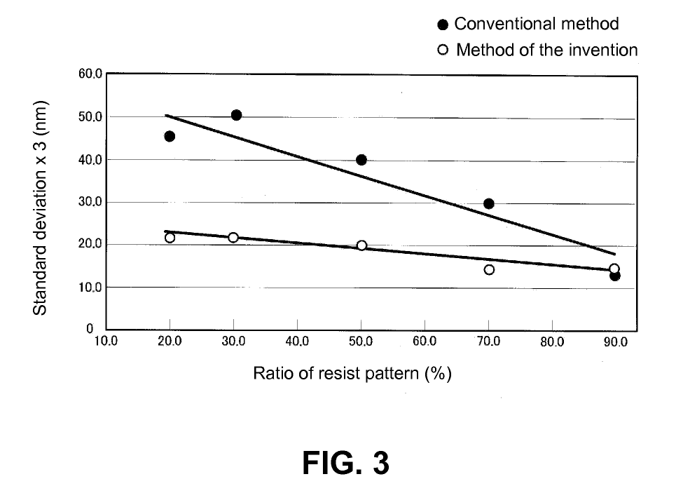

FIG. 3 is a graph showing a relationship between a ratio (an area) of the resist pattern and a dimensional variance (a standard deviation of 213 points over a surface of a wafer ×3) of the resist pattern according to the embodiment of the present invention.

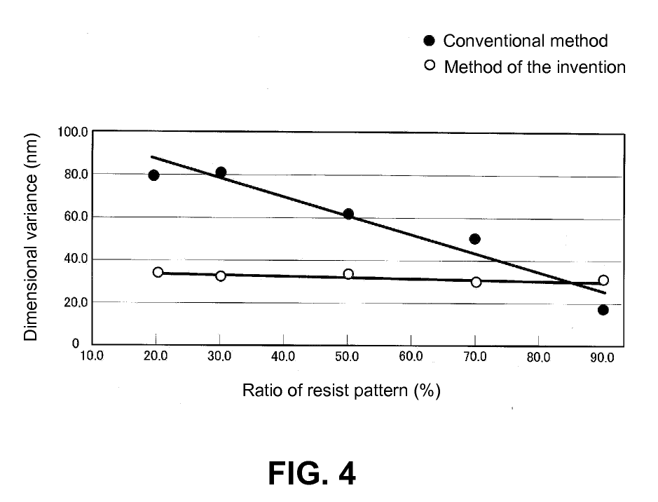

FIG. 4 is a graph showing a relationship between the ratio (the area) of the resist pattern and a dimensional variance (a difference between a maximum dimension and a minimum dimension) of the resist pattern according to the embodiment of the present invention.

As shown in FIGS. 3 and 4, when a resist pattern is formed with a conventional method, the dimensional variance is deteriorated as the ratio of the resist pattern decreases. On the other hand, when the resist pattern is formed with the method of the invention, it is possible to maintain the dimensional variance at an excellent level.

In the embodiment, it is preferred that the first resist pattern is a trimming pattern having a constant (areal) ratio between a resist remaining portion and a resist dissolving portion in the second exposure process and the second developing process.

As described above, whereas the embodiment of the present invention is explained, the present invention is not limited thereto and is capable of being modified.

For example, in the embodiment described above, the developing method is a paddle method, and the present invention is applicable to a developing method of other type such as a dipping method. Further, in the embodiment described above, the semiconductor wafer 10 repeatedly stops and rotates in the developing process. Alternatively, the semiconductor wafer 10 may stop and rotate just once in the developing process.

The disclosure of Japanese Patent Application No. 2009-077566, filed on Mar. 26, 2009, is incorporated in the application by reference.

While the invention has been explained with reference to the specific embodiments of the invention, the explanation is illustrative and the invention is limited only by the appended claims.

What is claimed is:

1. A method of producing a specific resist pattern comprising the steps of:
forming a resist layer on the semiconductor substrate;
performing a first exposure process on the resist layer;
performing a first developing process for developing the resist layer to form a first resist pattern having an excess region;
performing a first cleaning process;
performing a second exposure process on the first resist pattern;
performing a second developing process on the first resist pattern to remove the excess region from the first resist pattern so that a second resist pattern corresponding to the specific resist pattern is formed; and
performing a second cleaning process.

2. The method of producing the resist pattern according to claim 1, wherein, in the step of forming the resist layer on the semiconductor substrate, said resist layer is formed of a positive type resist.

3. The method of producing the resist pattern according to claim 1, wherein, in the step of performing the first cleaning process to form the first resist pattern, said first pattern has a constant ratio between the excess region and a remaining region after the second exposure process and the second cleaning process.
